(19) United States
(12) Patent Application Publication
(10) Pub. No.: US 2026/0220400 A1
(43) Pub. Date: Jul. 30, 2026

(54) METHOD FOR DETERMINING THE STATE OF AN ANTENNA

(71) Applicant: BANKS AND ACQUIRERS INTERNATIONAL HOLDING, SURESNES (FR)

(72) Inventors: Maxime GOULON, SURESNES (FR); Mampionona RAKOTOBE, SURESNES (FR)

(21) Appl. No.: 19/141,397

(22) PCT Filed: Dec. 20, 2023
(86) PCT No.: PCT/EP2023/086996

§ 371 Date: Jun. 20, 2025

(30) Foreign Application Priority Data
Dec. 23, 2022 (FR) FR2214364

(51) Int. Cl. G06K 7/10; G01R 29/08; H04B 5/43

(52) U.S. Cl. CPC G06K 7/10297; G01R 29/0878; H04B 5/43

(57) ABSTRACT

A method for determining a state of a near-field communication antenna, implemented by computer within a terminal including the near-field communication antenna and a near-field communication integrated circuit configured to be connected to the antenna. The method includes steps of determining, within the integrated circuit, at least one voltage or current value, and deducting, from the voltage or current value determined within the integrated circuit, an operating or malfunctioning state of the antenna.

### TECHNICAL FIELD

The invention relates to near field communication. In particular, it concerns “contactless” electronic payments between a payment terminal and a payment device.

### BACKGROUND

Near-field communication (NFC) is a short-range wireless communication technology enabling information to be exchanged between devices located a short distance apart. In particular, in the field of payment, it enables contactless payment to be made between a payment terminal and a payment device such as a bank card.

A terminal comprising a near-field communication function, such as a payment terminal configured to perform contactless transactions with a payment device, comprises a near-field communication antenna connected, via an impedance matching circuit, to a near-field communication integrated circuit. This near-field communication circuit generally comprises electronic components for powering and driving the antenna, configured to supply the antenna with signals to be transmitted and to process the signals received by the antenna. This near-field communication circuit is generally in the form of an electronic chip to which the impedance matching circuit is connected via one or two pins. In the field of payment, this near-field communication circuit is specifically configured to comply with security standards associated with contactless transactions.

In the current state of the art, when a terminal comprising a near field communication function fails, it is necessary to dismantle the terminal to identify the source of the malfunction. A fault may originate in the antenna, but also in the impedance circuit, the near-field communication integrated circuit, or another element of the terminal. It is therefore necessary to examine each of these elements in turn.

Such an operation is complex, time-consuming and tedious.

### SUMMARY

One of the aims of the invention is to identify quickly and immediately, within a terminal equipped with a near-field communication function, whether the antenna is the cause of a malfunction in the near-field communication function, without having to dismantle the terminal and examine the antenna.

To this end, the invention covers a method of determining a state of a near-field communication antenna, implemented by computer within a terminal comprising:
the near-field communication antenna,
a near-field communication integrated circuit configured to be connected to the antenna,
wherein the following steps are implemented:
determination, within the integrated circuit, of at least one voltage or current value,
deduction, from the voltage or current value determined within the integrated circuit, of an operating or malfunctioning state of the antenna.

Indeed, outside the scope of the invention, this current or voltage value internal to the near field communication integrated circuit is used for other purposes, in particular for regulating or amplifying a signal within the circuit. However, it appears that if the antenna fails, this value varies systematically and in a similar way. By obtaining it at all times, it is therefore possible to deduce an antenna fault, without having to dismantle the terminal and examine the antenna.

Other optional features, taken alone or in combination, follow.

Advantageously, the near-field communication integrated circuit comprising:
a transmitter for transmitting a signal to the antenna,
a dynamic power control unit for regulating a power of a signal transmitted by the transmitter to the antenna,
the step of determining a value comprises a step of determining a voltage across the transmitter and/or a step of determining a current flowing through the transmitter.

Thus, in the case where the integrated circuit has a transmitter and a control unit enabling the power supplied to the antenna to be regulated, it is at least one of the values from among a voltage value and a current value associated with this transmitter that enables the state of the antenna to be deduced. The control unit varies these values so as to comply with a setpoint. However, it appears that it varies these values differently when the antenna fails.

Preferably, the deduction step comprises deducing, from the voltage and/or current determined, at least one operating or malfunctioning state of the antenna from among the following states:
the antenna is connected to the communication integrated circuit;
the antenna is disconnected from the communication integrated circuit;
one track of the antenna is disconnected from the communication circuit;
two tracks of the antenna are disconnected from the communication circuit.

In fact, it appears that the control unit varies the current and/or voltage values in a specific way when the antenna is disconnected or when only one of its two tracks is disconnected. It is therefore possible to obtain a precise state of the antenna. If the value(s) determined show(s) that only one track is cut, it is possible to carry out a maintenance operation by configuring the antenna or other components of the terminal differently in view of this partial fault so that the near field communication function continues to operate. It is also possible to carry out a preventive or even predictive maintenance operation by replacing the antenna before the near field communication function fails completely.

Advantageously, since the communication integrated circuit comprising two signal reception pins intended to be connected to the antenna, the determining step comprises determining a signal amplitude value at the two reception pins.

Thus, in the case where the communication integrated circuit comprises these two pins and makes accessible an amplitude value associated with these two pins, it appears that this value varies as a function of the state of the antenna so that reading it makes it possible to deduce a state of the antenna.

Preferably, the deduction step comprises deducing, from the differential value determined, at least one operating or malfunctioning state of the antenna from among the following states:
the antenna is connected to the communication integrated circuit;
the antenna is disconnected from the communication integrated circuit or at least one track is cut.

The invention also provides a computer program comprising instructions which, when the program is executed by a computer, cause the computer to implement the steps of the method described above.

The invention also provides for a computer-readable recording medium comprising instructions which, when executed by a computer, cause the computer to implement the steps of the method described above.

The invention also provides for a terminal comprising:
a near field communication antenna,
a near field communication integrated circuit configured to be connected to the antenna,
a processor configured to implement the steps of the method described above.

By “configured to”, we mean that an element has means and/or settings specifically adapted to a particular use. Here, the processor has electronic components, a configuration, and is associated with computer programs, specifically adapted to the implementation of the processes described.

The invention also provides a terminal as described above, configured to make a contactless electronic payment.

In particular, its near-field communication integrated circuit is configured to comply with standards relating to contactless banking transactions.

### BRIEF DESCRIPTION OF THE FIGURES

The invention will be better understood on reading the following description, which is given by way of example only and with reference to the attached drawings in which:

FIG. 1 is a block diagram of a near-field communication integrated circuit used for the invention;

FIG. 2 is a flow diagram of a method of implementing the invention using the circuit of FIG. 1;

FIG. 3 is a block diagram of another near-field communication integrated circuit used for the invention;

FIG. 4 is a flow diagram of a method of implementing the invention using the circuit of FIG. 3.

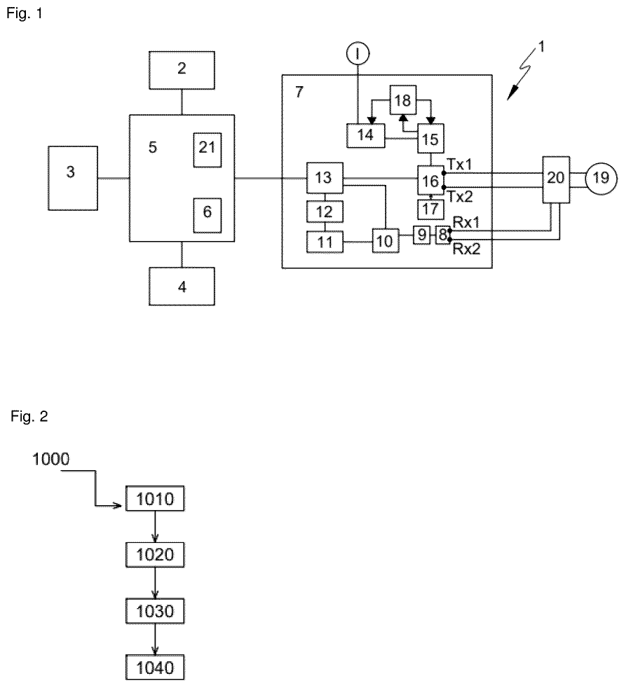

### DETAILED DESCRIPTION

Throughout the application, “near-field communication” is used to refer to any communication using near-field communication (NFC) technology. NFC technology is a short-range, high-frequency wireless communication technology enabling information to be exchanged between devices located within a short range of each other, generally ten centimetres or less. It is covered by norms and standards known to the person skilled in the art.

A device configured to use this technology is referred to in common parlance as an “NFC device”. An NFC device comprises at least one near-field communication antenna and a near-field communication integrated circuit connected to this antenna.

Throughout the application, “near-field communication antenna” means an antenna configured to use NFC technology. In particular, it has characteristics that comply with the norms or standards associated with NFC technology.

Throughout the application, “near field communication integrated circuit” means an integrated circuit comprising electronic components connected together to process signals to be transmitted by a near field communication antenna, or signals received by this antenna. This circuit also has characteristics that comply with the norms or standards associated with NFC technology.

In English, such a circuit is commonly called an “NFC IC” (IC for “integrated Circuit”). A near-field communication circuit may be referred to by other names known to those skilled in the art, such as “near-field communication reader” (“NFC reader”) or “near-field communication front end” (“NFC front end”). It could also be referred to as a near field communication electronic unit or a near field communication electronic module, except that the antenna is not part of this unit or module. In addition, the components forming the integrated near-field communication circuit are generally carried by a substrate and in a protective case. This assembly forms an electronic chip so that, for those skilled in the art, the terms “chip” and “integrated circuit” are generally synonymous. The near-field communication integrated circuit can therefore also be referred to as a “near-field communication chip”.

The figure shows a block diagram of a payment terminal 1. It includes a screen 2, a wireless communication module 3, a keyboard 4 and a processing unit 5 comprising a security controller and an application processor.

The processing unit 5 includes a cryptography and security key storage module 6. This processing unit 5 is configured to implement EMV standards, in particular EMV level 1, 2 and 3 standards. EMV stands for “Europay Mastercard Visa” and refers to the international security standard for bankcard payment methods. This processing unit (5) is connected via an SPI interface to a radio protocol interface and processing module (13) belonging to a near field communication integrated circuit (7).

The processing unit 5 also includes a computer-readable recording medium containing instructions which, when executed by a computer, in this case by the processing unit 5, cause the latter to implement the steps of the method 100 described below. In other words, unit 5 includes, in recorded form, a computer program 21 comprising instructions which, when the program is executed by a computer, in this case by processing unit 5, cause the latter to implement the steps of method 100. This program is installed beforehand by loading an application into terminal 1.

The near field communication integrated circuit 7 is the circuit marketed under the reference PN5190 by the company NXP Semiconductors N.V.

In accordance with the description provided by its manufacturer, this integrated circuit 7 comprises the elements described below. The circuit is provided with two receiving terminals Rx1 and Rx2 for receiving two tracks of a near field communication antenna. An automatic gain control module 8 is connected to terminals Rx1 and Rx2. This module 8 is connected to a baseband filter 9. This filter 9 is connected to an analogue-to-digital converter 10. This converter 10 is connected to a digital signal processor 11. This processor 11 is connected to a contactless communication test module 12. This module 12 is connected to the interface and radio protocol processing module 13. The integrated circuit 7 also includes a DC-DC converter 14, supplied by an electrical power supply external to the circuit 7. This converter 14 supplies, within the circuit 7, a transmitter 16, via a voltage regulator 15. This voltage regulator 15, known as a “low-drop out voltage regulator” or “LDO regulator”, regulates the voltage to be supplied to the terminals of the transmitter 16. Circuit 7 is also equipped with two transmission terminals Tx1 and Tx2 for receiving two tracks from a near-field communication antenna. The transmitter 16 is connected to these two terminals. A waveform control module 17 is connected to the transmitter 16.

Finally, the integrated circuit 7 includes a dynamic power control unit 18 for regulating the power of a signal transmitted by the transmitter 16 to an antenna. A signal transmitted by the antenna must comply with certain standards, particularly power standards. These standards are safety standards, such as EMV standards. To ensure compliance with these standards, unit 18 is configured to check a supply voltage, called VDDPA by the manufacturer, at the terminals of transmitter 16. Depending on its result, the control unit 18 modifies a current value, called ITVDD by the manufacturer, passing through the transmitter 16, so that the power at the terminals of the transmitter 16 complies with the established safety standards. The ITVDD current and VDDPA voltage values are stored in a register in the unit 18, or associated with the unit 18, and can be read.

The payment terminal 1 also includes a near field communication antenna 19. It has two tracks. Each of these two tracks is connected to an impedance matching circuit 20. The impedance matching circuit 20 connects the antenna 19 to the integrated circuit 7 via the transmit terminals Tx1 and Tx2 on the one hand and via the receive terminals Rx1 and Rx2 on the other.

In nominal operation, when a payment device, such as a bank card, is brought close to the antenna 20, contactless communications are carried out using NFC technology between the antenna and the device. And the signals received and transmitted are processed by the near field communication integrated circuit 7.

With reference to FIG. 2, the method 1000 for implementing the invention will now be described. It is implemented by the processing unit 5, by executing the computer program 21.

In step 1010, the voltage value VDDPA is determined. This is accessed from the control unit 18.

In step 1020, the current value ITVDD is determined. This is accessed from the control unit 18.

In step 1030, a state of operation or malfunction of the antenna is deduced from the voltage value VDDPA and the current value ITVDD, from one of the following states:
the antenna is connected to the communication integrated circuit;
the antenna is disconnected from the communication integrated circuit;
one track of the antenna is disconnected from the communication circuit;
two tracks of the antenna are disconnected from the communication circuit.

In fact, it appears that these states can be deduced from these values in accordance with the following table.

TABLE 1

| Antenna status | ITVDD (mA) | VDDPA (V) |
|---|---|---|
| Antenna connected | 255 | 5.7 |
| Antenna disconnected | 225 | 2.2 |
| One track cut | 255 | 2.2 |
| Two tracks cut | 225 | 2.2 |

These two parameters can be used to deduce the precise state of the antenna, i.e. whether it is connected, disconnected or has one or two tracks cut.

It is also possible to deduce a less precise state of the antenna using just one of these two parameters. If the value of ITVDD is 255 mA, we already know that either the antenna is connected or only one of its tracks is cut. Similarly, if the value of VDDPA is 2.2V, we know that it has a fault, either a disconnection or a cut in one or both of its tracks.

Step 1040 is the antenna status alert. In this way, the status deduced from the antenna can be indicated to a user on a screen of the terminal 1. In this way, a user using the application including program 21 on the terminal 1 obtains the status of the antenna 19 of this terminal without having to dismantle it and examine each of the components. This is particularly useful if the terminal appears to be malfunctioning. It is also useful for preventive maintenance operations. For example, if a fault is detected only on one track of the antenna, it may be possible to continue to operate the terminal by configuring it appropriately, or on the contrary, it may be possible to replace the antenna before the fault gets worse.

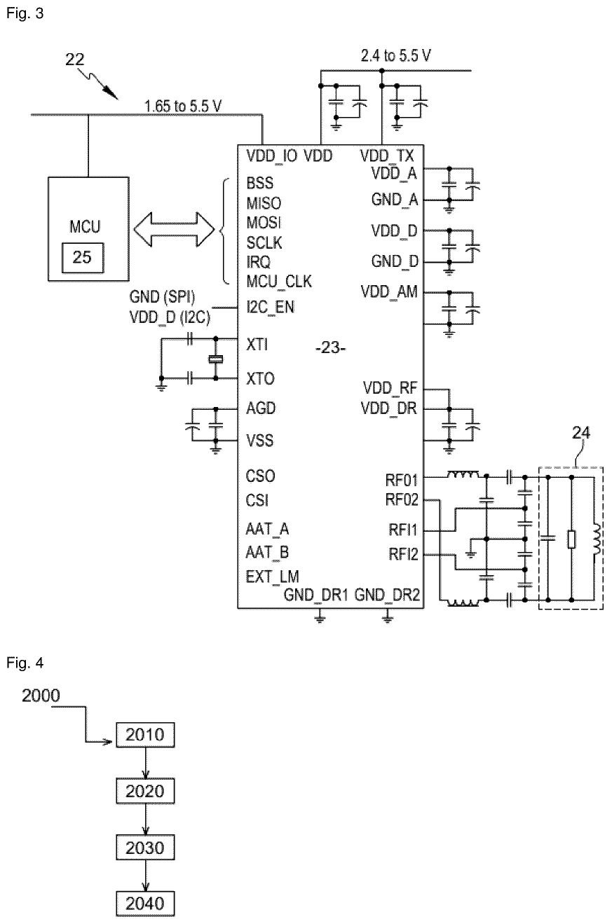

FIG. 3 illustrates another payment terminal 22. It comprises a near field communication integrated circuit 23 distinct from the integrated circuit 7 of the terminal 1, and a near field communication antenna 24.

The integrated circuit 23 is the circuit marketed as ST25R3916 by STMicroelectronics. This circuit 23 has various connection pins.

These include two signal transmission pins RFO1 and RFO2, and two signal reception pins RFI1 and RFI2. These four pins are connected to the antenna 24 via an impedance circuit.

As described by the circuit manufacturer, within the near field communication integrated circuit 23, an amplitude detector converts a differential back-modulation radio signal received between the two RFI1 and RFI2 reception pins into a proportional voltage value, known as the signal amplitude value. This voltage value is then converted into a digital value and stored in a register of an analogue-to-digital converter of circuit 23, by a value coded on eight bits. The presence of these two terminals instead of a single receive terminal, and the conversion of the respective signals received at these terminals into an amplitude value, is intended to increase the reliability of near-field communication.

Circuit 23 is connected to an MCU (Microcontroller Unit) of payment terminal 22. This MCU plays the same role as the terminal 1's processing unit 5. It implements a computer program 25 comprising instructions which, when the program is executed by a computer, in this case by the MCU, cause the MCU to implement the steps of a process 2000. In other words, the MCU includes, in recorded form, a computer program 25 comprising instructions which, when the program is executed by a computer, in this case by the MCU, cause it to implement the steps of the 2000 process. This program 25 is installed beforehand by loading an application in the terminal 22.

In nominal operation, when a payment device, such as a bank card, is brought close to the antenna 24, contactless communications are carried out using NFC technology between the antenna and the device. And the signals received and transmitted are processed by the near field communication integrated circuit 23.

With reference to FIG. 4, the 2000 method for implementing the invention will now be described. It is implemented by the MCU, by executing the computer program 225.

In step 2010, the value of the signal amplitude is determined. It is accessed from the register of circuit 23 in which it is stored.

In step 2020, a state of operation or malfunction of the antenna is deduced from the amplitude value, from one of the following states:
the antenna is connected to the integrated communication circuit;
the antenna is disconnected from the integrated communication circuit or has at least one cut-off track.

In fact, it appears that these states can be deduced from these values in accordance with the following table.

TABLE 2

| State of the antenna | Amplitude value |
|---|---|
| Antenna connected | 155 |
| Antenna disconnected | 15 |
| One track cut | 15 |
| Two tracks cut | 15 |

This amplitude value is used to deduce whether the antenna is connected and has its two tracks functional, or whether it has a connection or cut fault.

Step 2030 is the antenna status alert. The user manipulating the application associated with program 25 is therefore aware of the state of the antenna.

The two modes of implementation described have in particular in common the fact of diverting the use of internal values of the near-field communication integrated circuits for the purpose of determining the state of the near-field communication antenna. In the first implementation mode 1000, the voltage and current values used are normally intended to limit the magnetic field of the antenna in order to comply with standards. In the second implementation mode 2000, the amplitude value is intended to improve transmission reliability. Determining the state of the antenna by means of these values is therefore an unexpected effect.

The invention is not limited to the embodiments shown and other embodiments will become apparent to the person skilled in the art.

1. A method of determining a state of a near-field communication antenna, implemented by computer within a terminal comprising:
the near-field communication antenna, and
a near-field communication integrated circuit configured to be connected to the antenna,
wherein the following steps are implemented:
determining, within the integrated circuit, at least one voltage or current value,
deducing, from the voltage or current value determined within the integrated circuit, an operating or malfunctioning state of the antenna.

2. The method according to claim 1, wherein the step of determining at least one voltage or current value comprises accessing a register of the integrated circuit in which the value is recorded.

3. The method according to claim 1, wherein,
the near-field communication integrated circuit comprises:
a transmitter for transmitting a signal to the antenna, and
a dynamic power control unit for regulating a power of a signal transmitted by the transmitter to the antenna, and
the step of determining a value comprises a step of determining a voltage across the transmitter and/or a step of determining a current flowing through the transmitter.

4. The method according to claim 3, wherein the step of deducing comprises deducing, from the voltage and/or current determined, at least one operating or malfunctioning state of the antenna from among the following states:
the antenna is connected to the communication integrated circuit;
the antenna is disconnected from the integrated communication circuit;
one track of the antenna is disconnected from the communication circuit;
two tracks of the antenna are disconnected from the communication circuit.

5. The method according to claim 2, wherein,
the communication integrated circuit comprises two signal reception pins intended to be connected to the antenna,
the determining step comprises determining a signal amplitude value at the two reception pins.

6. The method according to claim 5, wherein the step of deducing comprises deducing, from a determined differential value, at least one operating or malfunctioning state of the antenna from among the following states:
the antenna is connected to the communication integrated circuit;
the antenna is disconnected from the communication integrated circuit or at least one track is cut.

7. A computer program, on non-transitory computer-readable recording medium, comprising instructions which, when the program is executed by a computer, cause the computer to implement the steps of the method according to claim 1.

8. A non-transitory computer-readable recording medium comprising instructions which, when executed by a computer, cause the computer to implement the steps of the method according to claim 1.

9. A terminal comprising:
a near-field communication antenna,
a near-field communication integrated circuit configured to be connected to the antenna, and
a processor configured to implement the steps of the method according to claim 1.

10. Terminal according to claim 9, configured to make a contactless electronic payment.

11. The method according to claim 1, wherein,
the communication integrated circuit comprises two signal reception pins intended to be connected to the antenna, and
the determining step comprises determining a signal amplitude value at the two reception pins.

12. The method according to claim 11, wherein the step of deducing comprises deducing, from a determined differential value, at least one operating or malfunctioning state of the antenna from among the following states:
the antenna is connected to the communication integrated circuit;
the antenna is disconnected from the communication integrated circuit or at least one track is cut.
